(19) United States
(12) Patent Application Publication
(10) Pub. No.: US 2005/0166121 A1
(43) Pub. Date: Jul. 28, 2005

(54) Memory error tolerant integrated circuit used to process encoded data with on-chip memory array

(75) Inventor: John David Kaewell JR., Jamison, PA (US)

Correspondence Address: VOLPE AND KOENIG, P.C.;DEPT. ICC, UNITED PLAZA, SUITE 1600, 30 SOUTH 17TH STREET, PHILADELPHIA, PA, 19103, US

(73) Assignee: InterDigital Technology Corporation, Wilmington, DE (US)

(21) Appl. No.: 10/987,861

(22) Filed: Nov. 12, 2004

Related U.S. Application Data
(60) Provisional application No. 60/519,799, filed on Nov. 13, 2003.

(51) Int. Cl. H03M 13/00

(52) U.S. Cl. 714/758

(57) ABSTRACT

A circuit fault tolerant memory array uses input and output functions which scramble and descramble data being written to and read from the memory array. The data is provided to the memory array in scrambled form and the process of descrambling the data, combined with the scrambling of the data provides error correction. In addition, data is written to and read from the array in a manner such that specific stuck bits in the array are randomized in the circuit output. By using the scrambling/descrambling functions provided for other data processing functions, error correction is achieved without a significant additional processing overhead.

### CROSS REFERENCE TO RELATED APPLICATION(S)

This application claims the benefit of U.S. Provisional Application No. 60/519,799; filed on Nov. 13, 2003, which is incorporated by reference as if fully set forth.

### FIELD OF INVENTION

The present invention relates to error correction on semiconductor integrated circuit chips which are used for processing of encoded data. The invention finds particular use in communications, including wireless telecommunication; however can be applied to any of a large number of circuits which process encoded data.

### BACKGROUND

Part of the configuration of some signal processing circuits is an ability to process encoded data. This provides a robust means for transferring and decoding data, and also allows for the processing of large amounts of data using limited data bandwidth.

Embedded memories are typically tested by the manufacturer of an integrated circuit. If there are any defects in the memory, which can not be repaired, the integrated circuit is scrapped.

Static Random Access Memory (SRAM) is typically the densest portion of a communication integrated circuit in terms of transistors per unit area. This dense area also tends to be more susceptible to manufacturing defects. Very large embedded SRAMs can be implemented with redundancy to correct some defects and improve manufacturing yield at a cost of additional die area for the redundant circuits; however, smaller SRAMs, typically found in implementations of communication systems can not take advantage of repairable memory technology because of the overhead area cost. Because of the use of small embedded SRAMs, communication integrated circuits (ICs) can suffer from low manufacturing yields, increasing the price per IC.

One way to increase wafer yield is to provide redundancy in IC circuits. Through the use of switches, fuses and antifuses, matrixed elements of the IC are switched off and other elements added. This of course requires a corresponding redundancy of circuit elements, which can be significant because replacement normally is performed by substituting entire rows or columns of the array. The second approach would embed extra rows and columns into the memory array. At time of test if there is a bad row or column discovered, the redundant row or column is switched in through programmable fuses and antifuses.

Another way to increase wafer yield on memory devices is to provide error correction circuitry (ECC). The inclusion of EEC circuits around IC memories has been done by IC manufacturers at the cost of adding more bits of storage to the memory and additional encoding and decoding circuitry. This has the disadvantage of slowing process speeds, since data must be processed by the error correction circuitry, resulting in additional delay time. In addition, the use of error correction increases the cost of the circuit because the error correction takes up “real estate” on the chip and requires additional circuit design.

One redundancy approach uses parity bits for every stored data word. The parity bits are used with standard error correction coding techniques such as Bose-Chaudhuri-Hocquenghem code (BCH code) or Reed-Solomon error correction. Each of these techniques have costs in terms of extra die area for the added redundancy and ECC circuitry and possibly added test time.

Accordingly, it is desirable to have alternate approaches to memory fault tolerance.

### SUMMARY

In accordance with the present invention, digital signal processing circuit includes a fault tolerant memory array. The digital signal processing circuit and memory array are provided in a system in which scrambler and de-scrambler circuits are used to randomly distribute errors that might otherwise be clustered together. Spread spectrum communication algorithms such as dispreading algorithms can usually reliably recover signals with errors if the errors are randomly distributed. The scrambling code is selected as one which will break up clumps of errors into a more Gaussian or random distribution. The inherent robustness of typical spread-spectrum receiver circuits can often reliably recover the original transmitted data signal from the received signal having errors. The implementation of this invention results in treating the memory error distorted receive signal as if it was received through a communication channel.

### BRIEF DESCRIPTION OF THE DRAWINGS

FIG. 1 is a schematic block diagram showing components used in a fault tolerant memory array in accordance with the present invention.

FIG. 2 is a schematic block diagram showing the invention implemented in a wireless communications system.

FIG. 3 is a schematic block diagram showing the invention implemented with a barrel shifter circuit.

FIG. 4 is a schematic block diagram showing components used in a fault tolerant memory array in accordance with an alternate embodiment of the present invention, in which data is provided directly to the scrambler.

FIG. 5 is a schematic block diagram showing components used in a fault tolerant memory array in accordance with an alternate embodiment of the present invention, in which descrambled data is provided as an output.

FIG. 6 is a schematic block diagram showing components used in a fault tolerant memory array in accordance with an alternate embodiment of the present invention, in which data is provided to the memory array in scrambled form.

FIG. 7 is a schematic block diagram showing components used in a fault tolerant memory array in accordance with an alternate embodiment of the present invention, in which data is output in scrambled form.

### DETAILED DESCRIPTION OF THE PREFERRED EMBODIMENTS

Hereafter, a wireless transmit/receive unit (WTRU) includes but is not limited to a user equipment, mobile station, fixed or mobile subscriber unit, pager, or any other type of device capable of operating in a wireless environment. When referred to hereafter, a base station includes but is not limited to a Node-B, site controller, access point or any other type of interfacing device in a wireless environment.

According to the present invention, a scrambler and a de-scrambler are used in data transfer which is implemented through a memory array. Data read into the memory array in scrambled form and data read out is descrambled. The scrambling of the data is performed in a manner which randomly distributes or breaks apart clustered errors. The scrambling/descrambling functions provided for other data processing functions, and so processing overhead is not significantly increased. Scrambling and descrambling of data is often implemented in wireless communications systems, including CDMA and other wireless slotted communications systems, including systems in which multiple WTRUs communicate through one or more base stations. In a wireless channel, the Rayleigh fading phenomena often causes a burst of errors. A common technique to deal with fading channels is to use error correction encoding in conjunction with time interleaving at the transmitter. De-interleaving and error correction decoding are then performed at the receiver. Error correction techniques work better with randomly distributed errors versus clumped error patterns.

According to the present invention, error correction techniques used in memory are combined with error correction techniques used in combination with spreading techniques already embedded in communication waveforms. This provides an efficient way to recover from memory defects on the baseband chip. This avoids a need to include EEC circuits around IC memory circuits and thereby avoids the cost of adding more bits of storage to the memory as well as avoiding additional encoding and decoding circuitry.

To illustrate, data in communication systems typically is encoded using error correction codes. Instead of encoding the data with an error correction code prior to descrambling or using redundant memory elements, the error correction coding already present in the data is used to correct our identity errors within the descrambled data. Also, in spread spectrum communications, the spreading codes introduce redundancy in the transmitted waveform which can allow the receiver despreader to correctly recover a corrupted signal. As a result, error correction coding is not required by the memory array and memory redundancy is not required due to the redundance inherent with the raw data's error correction coding and/or the signal's spreading code.

Additionally, the error correction can be performed in the normal error correction decoding of the communication signal. To illustrate, communication data is error correction encoded, such as turbo encoded. The encoded data is scrambled. The descrambled data is processed normally and any errors resulting from the memory storage are corrected along with any communication errors by the error correction decoder, such as a turbo decoder. Since, typically, any error in the memory storage are negligible with respect to the communication channel errors, the decoded data will also typically have a negligible degradation in quality. Another example would be of a corrupted spread spectrum waveform being correctly de-spread in the receiver.

In one embodiment of the invention, the memory array is integrated into a digital signal processing circuit used as a part of a data communications circuit. The scrambling and descrambling of the data is performed as part of a communications protocol which includes an error correction function as part of the scrambling and descrambling. The scrambling and descrambling provides the error correction for the memory array, so that errors in memory array are corrected, without substantial overhead in terms of latency, processing or circuitry in order to provide the error correction function. These functions randomize the memory defects to take advantage of the inherent robustness of the communication algorithms.

According to a further aspect of the invention, the specific approaches to scrambling and de-scrambling data is selected in accordance with use memory error characterization data from manufacturing tests. This memory error characterization data is then used to optimize the scrambling operation.

While the scrambling and descrambling are shown in a manner whereby the data is processed as received, it is also possible to provide the scrambling and descrambling process remotely. This would be the case where the scrambled data is transferred or stored. According to the invention, it is possible to provide the error correction function without substantial memory redundancy, processing overhead or circuitry overhead by combining the scrambling/descrambling function with an error correction function.

In a particular embodiment, the invention provides an IC design which treats the embedded memories and their possible defects as another form of channel which can be tolerated by robust communication algorithms. This embodiment takes advantage of the inherent robust behavior of communication algorithms to tolerate memory errors, and results in lower cost communication ICs. This embodiment allows the utilization of ICs with non-correctable memory errors, effectively increasing manufacturing yields and lowering the cost per IC.

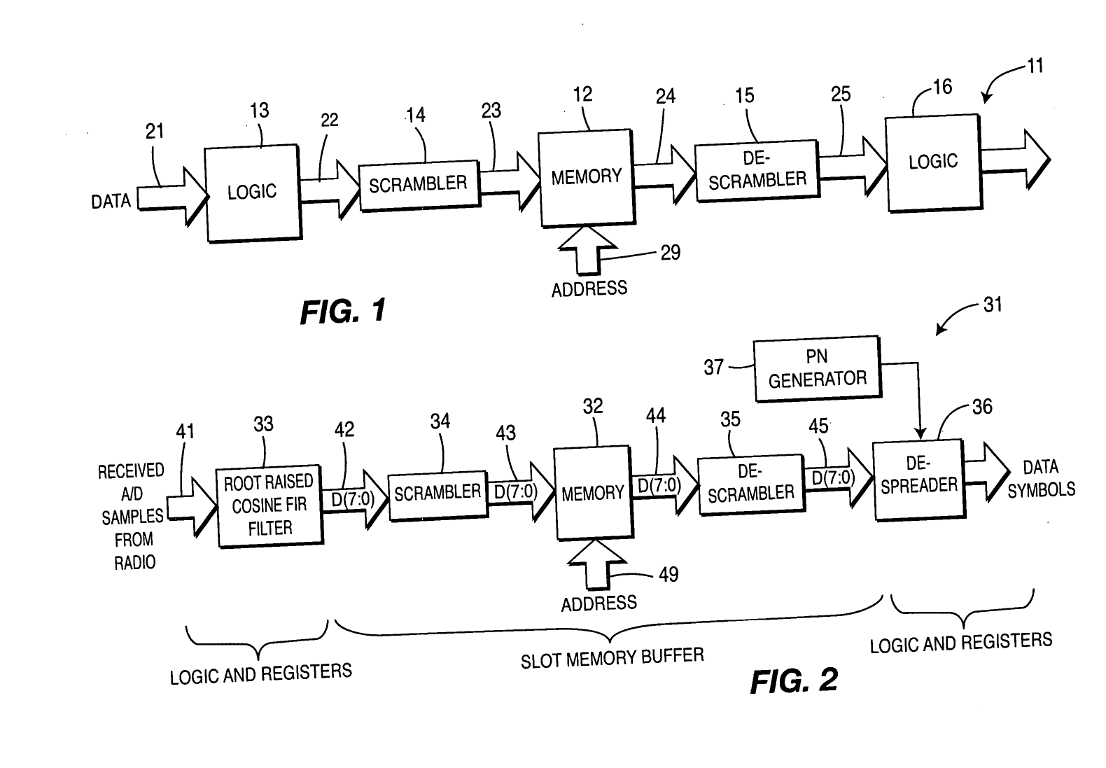

Correction occurs during descrambling or after descrambling using error correction codes present in stored data, to illustrate, FIG. 1 is a schematic block diagram showing components used in an IC circuit 11 with a fault tolerant memory array 12 in accordance with the present invention. The IC 11 includes the memory array 12, an input logic circuit 13, an input scrambler 14, an output descrambler 15 and an output logic circuit 16. Data 21 is supplied to the input logic circuit 13 which provides a data output 22. The data output is scrambled at the input scrambler 14 which provides a scrambled output 23 as a “write” input to the memory array 12. The memory array 12 provides its “read” output 24 in scrambled form to output descrambler 15, which in turn provides a descrambled output 25 to output logic circuit 16. Address commands 29 are provided to the memory array 12 in a conventional manner, although the address commands will include address information for data which is in scrambled form.

In FIG. 1, it is noted that the input and output logic 13, 16 may be provided as a common circuit, and the input scrambler 14 and the output descrambler 15 may be provided as a common circuit. It is also possible to combine the logic functions 13, 16 with the scrambler and descrambler functions 14, 15. It is possible to provide bidirectional transfer of data through the circuit of FIG. 1, in which case both the input scrambler 14 and output descrambler 15 provide scrambler/descrambler functions.

FIG. 2 is a schematic block diagram of an exemplary digital signal processing circuit implemented as a fault tolerant communications IC 31 for use in a wireless communications system. The digital signal processing circuit 31 includes a memory array 32, a root raised cosine FIR filter 33 as input logic, an input scrambler 34, an output descrambler 35 and an output de-spreader 36 as output logic. The memory array 32 is used as a slot memory buffer, and the root raised cosine FIR filter 33 and output de-spreader 36 function as logic and registers for the digital signal processing circuit 31. A PN generator 37 provides a PN signal to de-spreader 36. Received A/D samples 41 from an air interface or other external transfer medium are supplied to the root raised cosine FIR filter 33 which provides a data output 42. The data output is scrambled at the input scrambler 34 which provides a scrambled 43 output as a “write” input to the memory array 32. The memory array 32 provides its “read” output 44 in scrambled form to output descrambler 35, which in turn provides a descrambled output 45 to de-spreader 36. Address commands 49 are provided to the memory array 32 in a conventional manner, although the address commands will include address information for data which is in scrambled form.

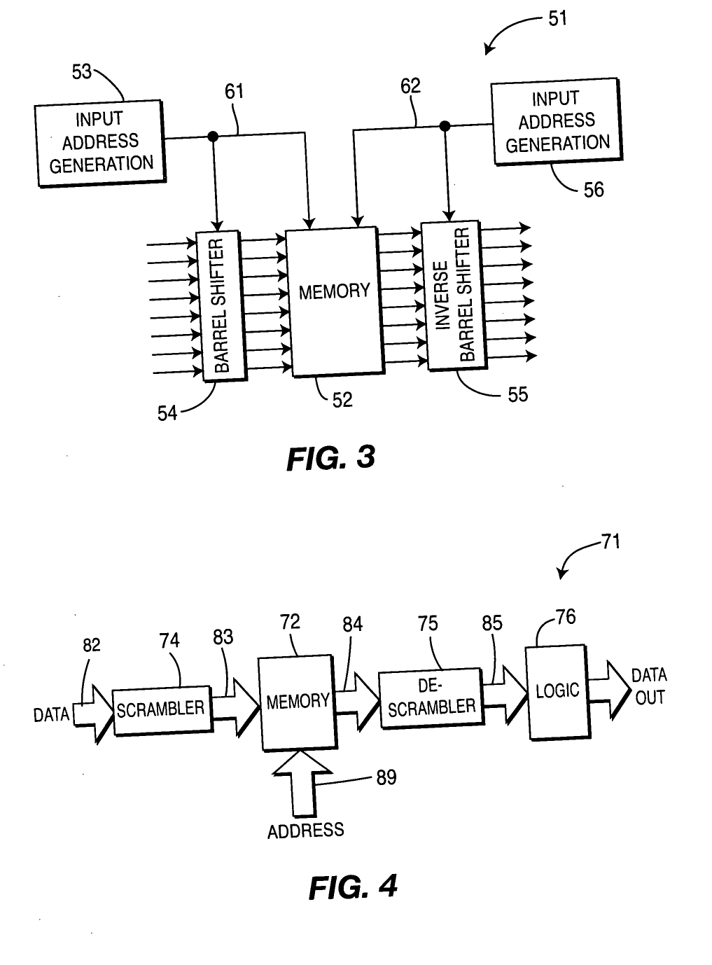

FIG. 3 is a schematic block diagram showing an embodiment of an IC 51 implemented with a barrel shifter circuit 54. This is a type of scrambler configuration which would help to randomize a stuck bit pattern, so that, for example, if the most significant bit of every 8^{th} byte is stuck at 1, the error is randomized. The IC 51 includes a memory array 52, an input address generation circuit 53, the barrel shifter circuit 54, an inverse barrel shifter circuit 55 and an output address generation circuit 56. Data is supplied to the input address generation circuit 53 which provides a data output 61. The data output is scrambled at the barrel shifter circuit 54 which provides a scrambled output as a “write” input to the memory array 52. The memory array 52 provides its “read” output in scrambled form to inverse barrel shifter circuit 55, which in turn provides a descrambled output to output address generation circuit 56. Address commands 62 are provided to the memory array 52 in a conventional manner, although the address commands will include address information for data which is in scrambled form.

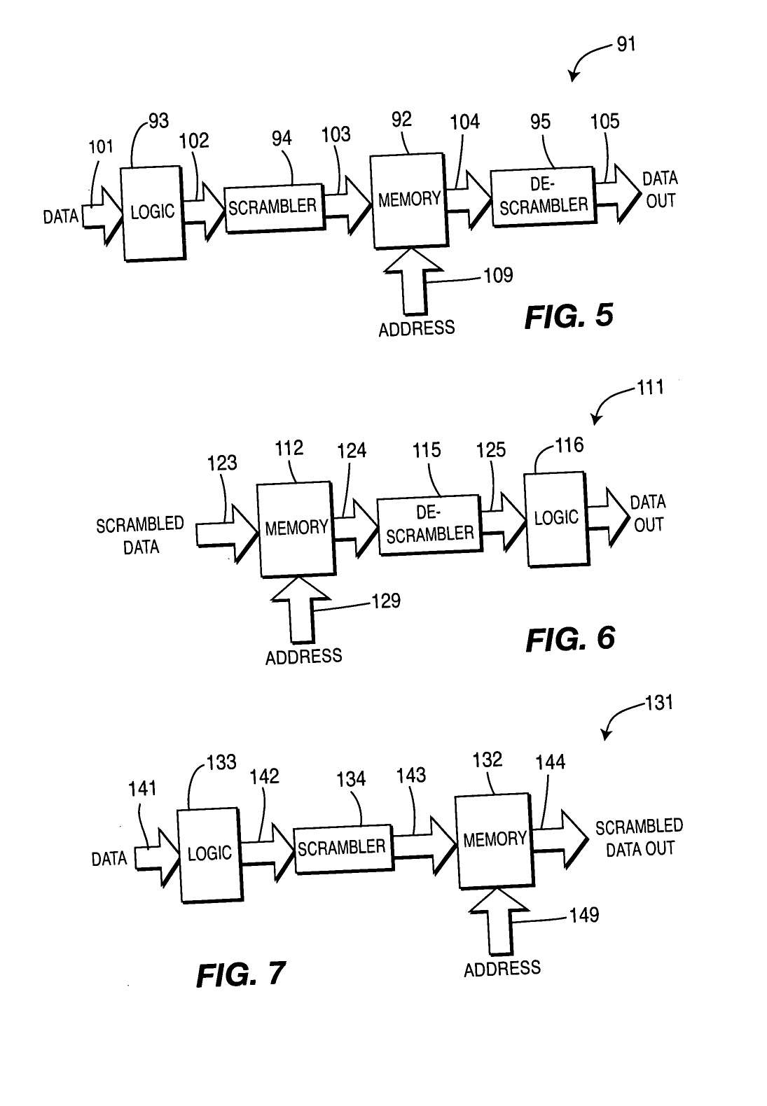

The specific examples incorporate exemplary approaches to scrambling and de-scrambling data to randomize memory data errors. Other approaches to scrambling and de-scrambling data may be used, provided that the scrambling and de-scrambling of the data is able to correct or randomize memory data errors. By way of example, it is often the case that logic operations and other data processing functions are performed on the data in encrypted or scrambled form, and it is possible to perform such logic functions along with other logic functions of the embodiments. It is further possible to implement the embodiments by providing data inputs and/or data outputs which are processed externally. FIGS. 4-5 show exemplary configurations which permit partial processing of the data external to the IC.

FIG. 4 is a schematic block diagram showing components used in an IC 71 with a fault tolerant memory array 72 in accordance with an alternate embodiment of the present invention, in which data is provided directly to the scrambler. The IC 71 includes the memory array 72, an input scrambler 74, an output descrambler 75 and an output logic circuit 76. The IC 71 does not utilize an input logic circuit, but instead data 82 is supplied directly to the input scrambler 74 which provides a scrambled output 83 as a “write” input to the memory array 72. The memory array 72 provides its “read” output 84 in scrambled form to output descrambler 75, which in turn provides a descrambled output 85 to output logic circuit 76. Address commands 89 are provided to the memory array 72 in a conventional manner, although the address commands will include address information for data which is in scrambled form.

FIG. 5 is a schematic block diagram showing components used in an IC 91 with a fault tolerant memory array 92 in accordance with an alternate embodiment of the present invention, in which descrambled data is provided as an output. The IC 91 includes the memory array 92, an input logic circuit 93, an input scrambler 94, and an output descrambler 95. Data 101 is supplied to the input logic circuit 93 which provides a data output 102. The data output is scrambled at the input scrambler 94 which provides a scrambled output 103 as a “write” input to the memory array 92. The memory array 92 provides its “read” output 104 in scrambled form to output descrambler 95, which in turn provides a descrambled output 105. The descrambled output 105 is provided as the data output without further processing the data through an output logic circuit. Address commands 109 are provided to the memory array 92 in a conventional manner, although the address commands will include address information for data which is in scrambled form.

It is further possible to provide data in scrambled or encrypted form and execute data error correction, as shown in FIGS. 6 and 7. FIG. 6 is a schematic block diagram showing components used in an IC 111 with a fault tolerant memory array 112 in accordance with an alternate embodiment of the present invention, in which data is provided to the memory array in scrambled form. The IC 111 includes the memory array 112, an output descrambler 115 and an output logic circuit 116. Data 123 is supplied in scrambled form as a “write” input to the memory array 112. The memory array 112 provides its “read” output 124, still in scrambled form to output descrambler 115, which in turn provides a descrambled output 125 to output logic circuit 116. Address commands 129 are provided to the memory array 112 in a conventional manner, although the address commands will include address information for data which is in scrambled form.

FIG. 7 is a schematic block diagram showing components used in an IC 131 with a fault tolerant memory array 132 in accordance with an alternate embodiment of the present invention, in which data is output in scrambled form. The IC 131 includes the memory array 132, an input logic circuit 133, and an input scrambler 134. Data 141 is supplied to the input logic circuit 133 which provides a data output 142. The data output is scrambled at the input scrambler 134 which provides a scrambled output 143 as a “write” input to the memory array 132. The data is read from memory array 132 provides its “read” output 144 in scrambled form as the data output. Address commands 149 are provided to the memory array 132 in a conventional manner, although the address commands will include address information for data which is in scrambled form.

1. A digital signal processing circuit with error correction comprising:
an error correction encoded interface providing error correction encoded data redundancy for data transferred between the digital signal processing circuit and an external transfer medium;
a memory array;
an input logic circuit;
an input scrambler circuit receiving data from the input logic circuit and providing a scrambled output as a write input to the memory array according to a scrambling protocol, the scrambled output including the error correction encoded data redundancy;
an output descrambler circuit receiving a read output from the memory array and descrambling the read output in accordance with the scrambling protocol; and
an output logic circuit receiving the descrambled read output from the output descrambler circuit.

2. The digital signal processing circuit of claim 1, comprising means for providing address control for memory read/write commands in accordance with the scrambling protocol.

3. The digital signal processing circuit of claim 1 wherein:
the input logic circuit provides a root raised cosine FIR filtered output; and
the output logic circuit despreading the descrambled read output.

4. The digital signal processing circuit of claim 1 wherein the input scrambler includes a barrel shifter and the output scrambler includes an inverse barrel shifter.

5. The digital signal processing circuit of claim 1, comprising:
the input scrambler including a barrel shifter and the output scrambler includes an inverse barrel shifter; and
the input and output logic circuits providing address generation, thereby providing a randomization of possible stuck bit patterns.

6. The digital signal processing circuit of claim 1 wherein the scrambler circuit implements a scrambling protocol selected in accordance with memory error characterization data.

7. The digital signal processing circuit of claim 1 wherein the scrambler circuit implements a scrambling protocol selected in accordance with memory error characterization data obtained from manufacturing tests, the memory error characterization data used to optimize the scrambling operation.

8. The digital signal processing circuit of claim 1 wherein combining the scrambling/descrambling function with the error correction function provides said error correction function without substantial memory redundancy, without substantial processing overhead and without substantial circuitry overhead.

9. A semiconductor integrated circuit chip including memory circuit, the semiconductor integrated chip comprising:
a memory array in which memory access operations perform write and read operations to and from the memory array;
an interface circuit providing error correction encoded data redundancy for data transferred between the digital signal processing circuit and an external transfer medium, the error correction encoded data provided in an encrypted form; and
circuitry to convert data provided in a memory access operation between an unencrypted form and said encrypted form, so that the memory array stores the data in the encrypted form, whereby the error correction function includes conversion of the data between unencrypted form and encrypted forms.

10. The semiconductor integrated circuit chip of claim 9 wherein the error correction includes a randomization of error bit location.

11. The semiconductor integrated circuit chip of claim 9 wherein the error correction includes operations performed by logic circuitry external to the semiconductor chip and operations performed by circuitry on the semiconductor chip.

12. The semiconductor integrated circuit chip of claim 9 wherein the error correction includes operations performed by logic circuitry on the semiconductor chip.

13. The semiconductor integrated circuit chip of claim 9, further comprising:
an input logic circuit; and
an input encrypting circuit receiving data from the input logic circuit and providing a encrypted output as a write input to the memory array according to an encrypting protocol.

14. The semiconductor integrated circuit chip of claim 9, further comprising:
an output deencrypting circuit receiving a read output from the memory array and deencrypting the read output in accordance with a protocol used for the encrypting; and
an output logic circuit receiving the deencrypted read output from the output deencrypting circuit.

15. The semiconductor integrated circuit chip of claim 9, further comprising:
an input logic circuit;
an input encrypting circuit receiving data from the input logic circuit and providing a encrypted output as a write input to the memory array according to an encrypting protocol; and
an output deencrypting circuit receiving a read output from the memory array and deencrypting the read output in accordance with the encrypting protocol.

16. The semiconductor integrated circuit chip of claim 9, further comprising:
an input encrypting circuit receiving data from the input logic circuit and providing a encrypted output as a write input to the memory array according to an encrypting protocol;
an output deencrypting circuit receiving a read output from the memory array and deencrypting the read output in accordance with the encrypting protocol; and
an output logic circuit receiving the deencrypted read output from the output deencrypting circuit.

17. The semiconductor integrated circuit chip of claim 9, comprising a circuit providing address control for memory read/write commands in accordance with a protocol used for the encrypting.

18. The semiconductor integrated circuit chip of claim 9 wherein:
an input logic circuit provides a root raised cosine FIR filtered output; and
an output logic circuit despreading the deencrypted read output.

19. The semiconductor integrated circuit chip of claim 9, comprising:
an input encrypting circuit, the input encrypting circuit including a barrel shifter; and
an output deencrypting circuit including an inverse barrel shifter.

20. The semiconductor integrated circuit chip of claim 9, comprising:
input and output encrypting circuits, the input encrypting circuit including a barrel shifter and the output encrypting circuit including an inverse barrel shifter; and
at least one input or output logic circuits providing address generation, thereby providing a randomization of possible stuck bit patterns.

21. The semiconductor integrated circuit chip of claim 9, comprising a encrypting circuit, the encrypting circuit implementing a encrypting protocol selected in accordance with memory error characterization data.

22. The semiconductor integrated circuit chip of claim 9, comprising a encrypting circuit, wherein the encrypting circuit implements a encrypting protocol selected in accordance with memory error characterization data obtained from manufacturing tests, the memory error characterization data used to optimize the encrypting operation.

23. The semiconductor integrated circuit chip of claim 9 wherein combining the encrypting/deencrypting function with the error correction function provides said error correction function without substantial memory redundancy, without substantial processing overhead and without substantial circuitry overhead.

24. A method of communicating data comprising:
receiving data;
storing the data in a scrambled format in a memory array;
providing a logic circuit to process the data in a descrambled format; and
converting the data between a scrambled form at the memory array and a descrambled form at the logic circuit and transfer the data between the memory array and the logic circuit according to a scrambling protocol, whereby a conversion of data stored in the memory array from the scrambled form provides an error correction function.

25. The method of claim 24, comprising communicating the data in the scrambled format over a communications link.

26. The method of claim 24, comprising communicating the data in the scrambled format over a wireless communications link.

27. The method of claim 24, comprising:
receiving a read output from the memory array and descrambling the read output in accordance with the scrambling protocol; and
receiving the descrambled read output from the output descrambler circuit.

28. The method of claim 24, comprising providing address control for memory read/write commands in accordance with the scrambling protocol.

29. The method of claim 24, comprising:
using an input logic circuit to provide a root raised cosine FIR filtered output; and
using an output logic circuit to despread the descrambled read output.

30. The method of claim 24, comprising:
using a barrel shifter as an input scrambler including and using an inverse barrel shifter as an output scrambler; and
the input and output logic circuits providing address generation, thereby providing a randomization of possible stuck bit patterns.

31. The method of claim 24, comprising implementing a scrambling protocol selected in accordance with memory error characterization data.

32. The method of claim 24, comprising implementing a scrambling protocol selected in accordance with memory error characterization data obtained from manufacturing tests, the memory error characterization data used to optimize the scrambling operation.

33. The method of claim 24 wherein combining the scrambling/descrambling function with the error correction function provides said error correction function without substantial memory redundancy, without substantial processing overhead and without substantial circuitry overhead.
